(19) United States
(12) Patent Application Publication
(10) Pub. No.: US 2023/0083863 A1
(43) Pub. Date: Mar. 16, 2023

(54) PROCESSING APPARATUS GROUP MANAGEMENT SYSTEM, PROCESSING APPARATUS GROUP MANAGEMENT METHOD, AND PROGRAM

(71) Applicant: SCREEN Holdings Co., Ltd., Kyoto (JP)

(72) Inventors: Shinji YAMAMOTO, Kyoto (JP); Kouhei NISHIKAWA, Kyoto (JP)

(21) Appl. No.: 17/942,693

(22) Filed: Sep. 12, 2022

(30) Foreign Application Priority Data
Sep. 16, 2021 (JP) 2021-151491

(51) Int. Cl. G05B 19/418

(52) U.S. Cl. CPC G05B 19/41875; G05B 2219/32368

(57) ABSTRACT

A processing apparatus group management system manages operational statuses of a processing apparatus group that is a group of substrate processing apparatuses. This system includes an information storage, a display, and a display controller. The information storage stores apparatus-specific information specific to each substrate processing apparatus, and apparatus operational information relating to the operational statuses of substrate processing apparatuses and continuously transmitted from the substrate processing apparatuses. The display controller causes the display to display the operational status of each substrate processing apparatus as an operational status table in accordance with the apparatus-specific information and the apparatus operational information about the substrate processing apparatus. The operational status table includes display items including an apparatus identifier used to identify each substrate processing apparatus, and the number of times an abnormal processing stop occurs in each substrate processing apparatus. This allows collective management of the operations statuses of the substrate processing apparatuses.

### CROSS-REFERENCE TO RELATED APPLICATION

This application claims priority benefit of Japanese Patent Application No. JP2021-151491 filed in the Japan Patent Office on Sep. 16, 2021, the entire disclosure of which is incorporated herein by reference.

### TECHNICAL FIELD

The present invention relates to a technique for managing the operational statuses of a processing apparatus group that is a group of a plurality of substrate processing apparatuses.

### BACKGROUND ART

Substrate processing apparatuses for processing semiconductor substrates (hereinafter, simply referred to as “substrates”) are conventionally configured for example such that FOUPs or the like that house substrates are opened at load ports, and substrates are taken out of the FOUPs or the like by an indexer robot. These substrates are passed from the indexer robot to a center robot and transported into one of a plurality of processing units by the center robot so as to be subjected to various types of processing.

When an abnormal condition has occurred in any of the processing units, these substrate processing apparatuses will exhibit lower substrate throughput and lower yields. Japanese Patent Application Laid-Open No. 2020-47077 (Document 1) discloses a technique for analyzing time-series data about the result of measurement of physical quantities (e.g., temperature) that indicate the condition of each processing unit and identifying a processing unit in which an abnormal condition has occurred and the cause of occurrence of the abnormal condition. Japanese Patent Application Laid-Open No. 2019-139416 (Document 2) and Japanese Patent Application Laid-Open No. 2019-140196 (Document 3) disclose techniques for making predictions about the occurrence of abnormal conditions by scoring.

Under normal circumstances, a large number of substrate processing apparatuses as described above are set up in one manufacturing site and operate at the same time. Thus, if the occurrence of abnormal conditions in the substrate processing apparatuses is to be managed for each substrate processing apparatus as in Document 1, an operator may have to make enormous efforts.

### SUMMARY OF INVENTION

The present invention is intended for a processing apparatus group management system for managing the operational statuses of a processing apparatus group that is a group of a plurality of substrate processing apparatuses, and it is an object of the present invention to collectively manage the operational statuses of the substrate processing apparatuses.

A processing apparatus group management system according to a preferable embodiment of the present invention includes an information storage that stores apparatus-specific information and apparatus operational information, the apparatus-specific information being information specific to each of a plurality of substrate processing apparatuses, and the apparatus operational information being information about operational statuses of the plurality of substrate processing apparatuses and being continuously transmitted from the plurality of substrate processing apparatuses, an information display, and a display controller that causes the information display to display the operational status of each of the plurality of substrate processing apparatuses as an operational status table in accordance with the apparatus-specific information and the apparatus operational information about the plurality of substrate processing apparatuses. The operational status table includes a plurality of display items that include an apparatus identifier used to identify each of the plurality of substrate processing apparatuses, and a number of times an abnormal processing stop occurs in each of the plurality of substrate processing apparatuses.

This processing apparatus group management system allows collective management of the operational statuses of the substrate processing apparatuses.

Preferably, the display controller performs at least one process out of a filtering process and a sorting process for one or more display items of the plurality of display items in the operational status table, and causes the information display to display a processing result.

Preferably, the information storage stores a processing condition for the at least one process, and the display controller reads and uses the processing condition stored in the information storage in the at least one process.

Preferably, the plurality of display items further include an installation area in which each of the plurality of substrate processing apparatuses is installed.

Preferably, the plurality of display items further include a number of times a normal processing stop occurs in each of the plurality of substrate processing apparatuses.

Preferably, the apparatus operational information includes information about occurrence of an event relating to prediction about occurrence of an abnormal condition in the plurality of substrate processing apparatuses, the display controller causes the information display to offer a notification display that provides notification of occurrence of the event in accordance with the apparatus operational information, and when the notification display is operated, the display controller causes the information display to display an event table in which event information about each event that has occurred is displayed in list form.

Preferably, the display controller performs at least one process out of a filtering process and a sorting process for one or more display items of a plurality of display items in the event table, and causes the information display to display a processing result.

Preferably, when one event is selected in the event table, the display controller causes the information display to display a condition of a module that is a cause of occurrence of the one event in a substrate processing apparatus in which the one event has occurred, in time sequence that includes an instant of time when the one event has occurred.

The present invention is also intended for a processing apparatus group management method for managing the operational statuses of a processing apparatus group that is a group of a plurality of substrate processing apparatuses. A processing apparatus group management method according to a preferable embodiment of the present invention includes a) storing apparatus-specific information and apparatus operational information, the apparatus-specific information being information specific to each of a plurality of substrate processing apparatuses, and the apparatus operational information being information about operational statuses of the plurality of substrate processing apparatuses and being continuously transmitted from the plurality of substrate processing apparatuses, and b) causing an information display to display the operational status of each of the plurality of substrate processing apparatuses as an operational status table in accordance with the apparatus-specific information and the apparatus operational information about the plurality of substrate processing apparatuses. The operational status table includes a plurality of display items that include an apparatus identifier used to identify each of the plurality of substrate processing apparatuses, and a number of times an abnormal processing stop occurs in each of the plurality of substrate processing apparatuses.

The present invention is also intended for a program for managing the operational statuses of a processing apparatus group that is a group of a plurality of substrate processing apparatuses. A program according to a preferable embodiment of the present invention is executed by a computer to a) store apparatus-specific information and apparatus operational information, the apparatus-specific information being information specific to each of a plurality of substrate processing apparatuses, and the apparatus operational information being information about operational statuses of the plurality of substrate processing apparatuses and being continuously transmitted from the plurality of substrate processing apparatuses, and b) cause an information display to display the operational status of each of the plurality of substrate processing apparatuses as an operational status table in accordance with the apparatus-specific information and the apparatus operational information about the plurality of substrate processing apparatuses. The operational status table includes a plurality of display items that include an apparatus identifier used to identify each of the plurality of substrate processing apparatuses, and a number of times an abnormal processing stop occurs in each of the plurality of substrate processing apparatuses.

These and other objects, features, aspects and advantages of the present invention will become more apparent from the following detailed description of the present invention when taken in conjunction with the accompanying drawings.

### BRIEF DESCRIPTION OF DRAWINGS

FIG. 1 is a conceptual diagram illustrating a configuration of a processing apparatus group management system according to one embodiment;

FIG. 2 is a plan view of one substrate processing apparatus;

FIG. 3 illustrates a configuration of a computer;

FIG. 4 is a block diagram illustrating functions achieved by the computer;

FIG. 5 is a flowchart of displaying an operational status table;

FIG. 6 illustrates the operational status table;

FIG. 7 illustrates a processing-stop summary table;

FIG. 8 illustrates an event table;

FIG. 9 shows one example of detailed display of an event;

FIG. 10 shows another example of detailed display of an event; and

FIG. 11 illustrates the operational status table.

### DESCRIPTION OF EMBODIMENTS

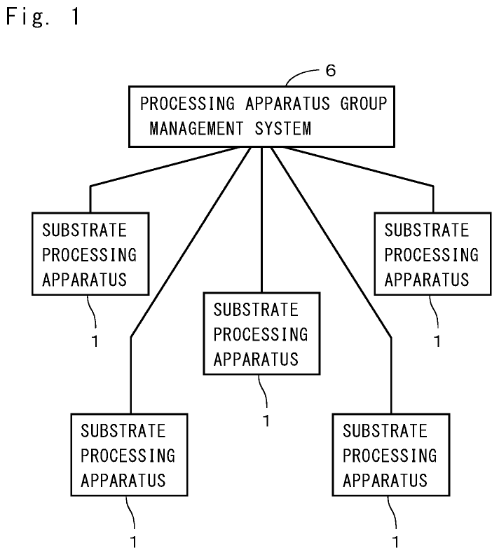

FIG. 1 is a conceptual diagram illustrating a configuration of a processing apparatus group management system 6 according to one embodiment of the present invention. In FIG. 1, a plurality of substrate processing apparatuses 1 connected to the processing apparatus group management system 6 are also illustrated. The processing apparatus group management system 6 is a system for managing the operational statuses of a processing apparatus group that is a group of the substrate processing apparatuses 1. The processing apparatus group management system 6 and the substrate processing apparatuses 1 may be connected by wireless connection or by wired connection. Note that the number of substrate processing apparatuses 1 connected to the processing apparatus group management system 6 is not limited to the example illustrated in FIG. 1, and may be changed as appropriate. For example, the number of substrate processing apparatuses 1 connected to the processing apparatus group management system 6 may be in the range of 100 to 200.

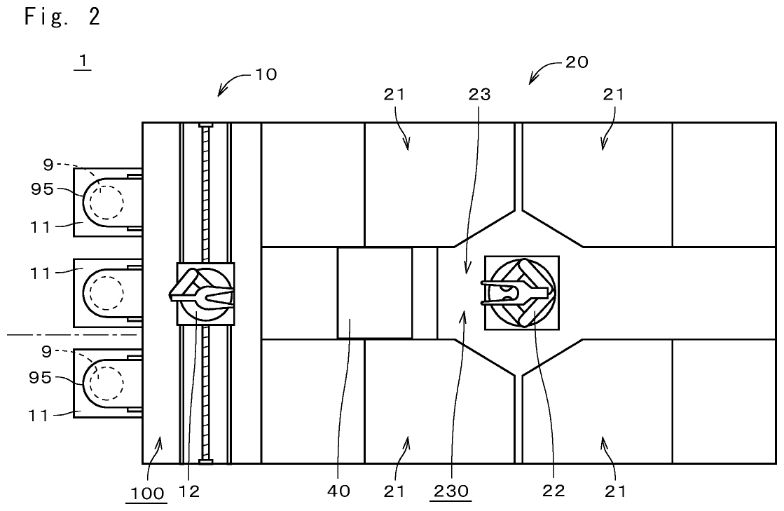

FIG. 2 is a plan view showing one example of a substrate processing apparatus 1 connected to the processing apparatus group management system 6. The substrate processing apparatus 1 is an apparatus that continuously performs processing on a plurality of approximately disk-shaped semiconductor substrates 9 (hereinafter, simply referred to as “substrates 9”). For example, the substrate processing apparatus 1 may perform liquid processing for supplying a processing liquid to the substrates 9.

The substrate processing apparatus 1 includes a plurality of load ports 11, an indexer block 10, a processing block 20, and a placement unit 40. Each of the load ports 11 serves as a holder that holds a carrier 95. The carrier 95 is capable of housing a plurality of disk-shaped substrates 9. For example, the carrier 95 may be a front opening unified pod (FOUP) that houses substrates 9 in its enclosed space. Each load port 11 may also serve as an opening/closing mechanism for opening and closing the carrier 95. The indexer block 10 has a side wall having openings and carrier shutters at positions that correspond respectively to the positions of the carriers 95 on the load ports 11. When substrates 9 are transported into and out of each carrier 95, the carrier 95 and the carrier shutter for this carrier are automatically opened and closed.

The indexer block 10 receives unprocessed substrates 9 from each carrier 95 and transfers the substrates 9 to the processing block 20. The indexer block 10 also receives processed substrates 9 transported out of the processing block 20 and transports these processed substrates 9 into each carrier 95. The indexer block 10 has an internal space 100 in which the indexer robot 12 is provided to transport substrates 9 into and out of each carrier 95.

The processing block 20 includes a transport path 23 used to transport substrates 9, and a plurality of processing units 21 arranged around the transport path 23. The transport path 23 has an internal space 230 in which the center robot 22 is provided to transport substrates 9 into and out of each processing unit 21. Each processing unit 21 performs predetermined processing on substrates 9.

The placement unit 40 is provided at the connection of the indexer block 10 and the processing block 20. The indexer robot 12 and the center robot 22 are accessible to the placement unit 40. The indexer robot 12 places unprocessed substrate 9 transported out of a carrier 95 on the placement unit 40. The center robot 22 transports the unprocessed substrates 9 out of the placement unit 40 and then into a processing units 21. The center robot 22 also places processed substrates 9 transported out of a processing units 21 on the placement unit 40. The indexer robot 12 transports the processed substrates 9 out of the placement unit 40 and then into a carrier 95.

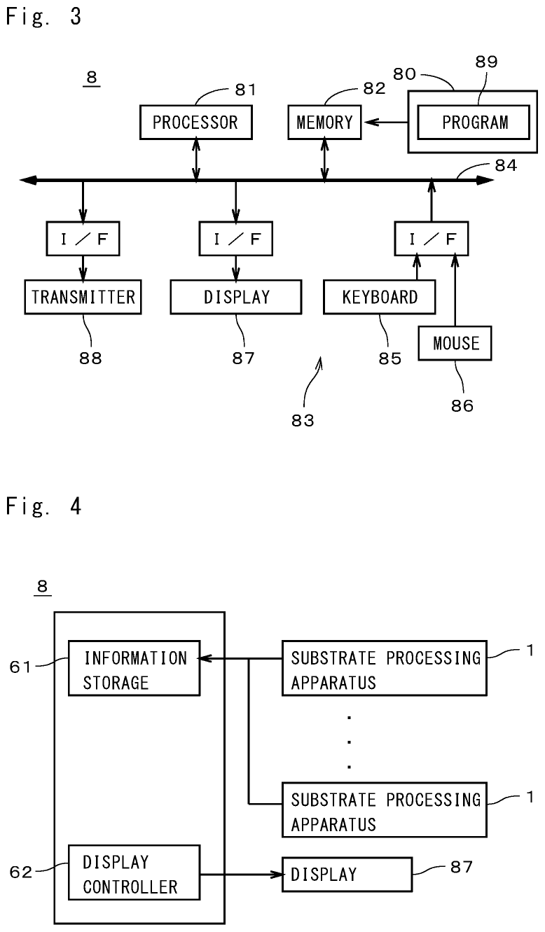

FIG. 3 illustrates a configuration of a computer 8 included in the processing apparatus group management system 6. The computer 8 is an ordinary computer that includes a processor 81, a memory 82, an input/output unit 83, and a bus 84. The bus 84 serves as a signal circuit that connects the processor 81, the memory 82, and the input/output unit 83. The memory 82 stores various types of information. For example, the memory 82 may read and store a program 89 stored in advance in a storage medium 80 that serves as a program product. The storage medium 80 may, for example, be a USB memory or a CD-ROM. The processor 81 executes various types of processing (e.g., numerical calculations and image processing), using the memory 82 and the like in accordance with, for example, the aforementioned program 89 stored in the memory 82. The input/output unit 83 includes a keyboard 85 and a mouse 86 that accept input from an operator, a display 87 that displays output and other information received from the processor 81, and a transmitter 88 that transmits output and other information received from the processor 81.

FIG. 4 is a block diagram illustrating functions achieved by the computer 8 executing the aforementioned program 89. As the functions achieved by the computer 8, the processing apparatus group management system 6 includes an information storage 61 and a display controller 62. The information storage 61 is primarily achieved by the memory 82 and stores various types of information such as apparatus-specific information and apparatus operational information, which will be described later, about a plurality of substrate processing apparatuses 1. The display controller 62 is primarily achieved by the processor 81 and causes the display 87 serving as an information display to display information such as the apparatus-specific information and the operational information stored in the information storage 61, in various display forms (i.e., formats).

The apparatus-specific information stored in the information storage 61 is information specific to each of the substrate processing apparatuses 1. This apparatus-specific information may include, for example, an apparatus identifier used to identify each substrate processing apparatus 1 from the other substrate processing apparatuses 1, the type (i.e., model) of each substrate processing apparatus 1, and an installation area in which each substrate processing apparatus 1 is installed.

The apparatus operational information stored in the information storage 61 is information about the operational statuses of the substrate processing apparatuses 1 and is continuously transmitted from the substrate processing apparatuses 1. For example, the apparatus operational information may include information that indicates the occurrence of an abnormal processing stop in each substrate processing apparatus 1 (hereinafter, also reoffered to as “abnormal stop information”) and information that indicates the occurrence of a normal processing stop in each substrate processing apparatus 1 (hereinafter, also referred to as “normal stop information”).

The abnormal processing stop described above may refer to, for example, an unscheduled stop of processing in a substrate processing apparatus 1, such as a failure to dismount substrates 9 on a load port 11 or disability of processing due to clogging in the nozzle of a processing unit 21. Meanwhile, the normal processing stop described above may refer to, for example, a scheduled stop of processing in a substrate processing apparatus 1, such as regular automatic maintenance of a processing unit 21.

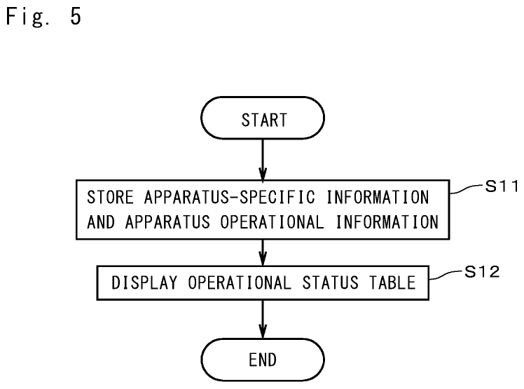

In the processing apparatus group management system 6, the information storage 61 stores the apparatus-specific information and the apparatus operational information as illustrated in FIG. 5 (step S11). Then, the display controller 62 causes the display 87 to display the operational status of each substrate processing apparatus 1 as an operational status table in accordance with the apparatus-specific information and the apparatus operational information about the substrate processing apparatuses 1 (step S12).

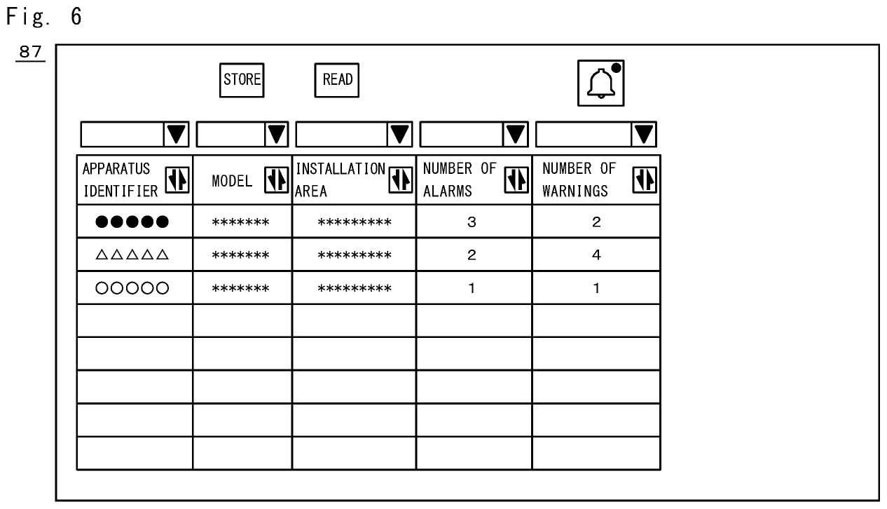

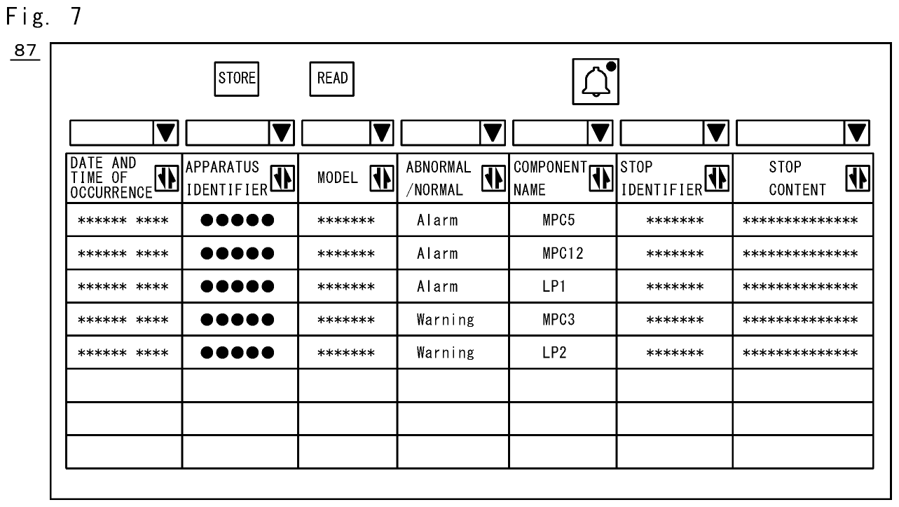

FIG. 6 shows one example of an operational status table 71 displayed on the display 87 by the display controller 62. In the operational status table 71, information about a plurality of display items is arranged in a row direction for each of a plurality of substrate processing apparatuses 1 arranged in a column direction. The display items may include, for example, an apparatus identifier used to identify each of the substrate processing apparatuses 1, the model of each of the substrate processing apparatuses 1, the installation area in which each of the substrate processing apparatuses 1 is installed, the number of times an abnormal processing stop has occurred in each of the substrate processing apparatuses 1 (hereinafter, also referred to as the “number of alarms”), and the number of times a normal processing stop has occurred in each of the substrate processing apparatuses 1 (hereinafter, also referred to as the “number of warnings”). In FIG. 6, characters and numbers that are to be described in the fields of the apparatus identifier, the model, and the installation area are replaced by asterisks or other symbols. The same applies to FIGS. 7, 8, and 11, which will be described later.

The aforementioned number of alarms refers to the number of abnormal processing stops currently occurring in each substrate processing apparatus 1. The number of warnings refers to the number of normal processing stops currently occurring in each substrate processing apparatus 1. In the example illustrated in FIG. 6, the operational status table 71 does not display substrate processing apparatuses 1 whose number of alarms and number of warnings are both zero. The display items described above are, however, not limited to the example described above, and may be modified in various ways.

The number of alarms in the operational status table 71 is updated based on the apparatus operational information continuously transmitted from each of the substrate processing apparatuses 1. The number of alarms increases when a new abnormal processing stop has occurred in any of the substrate processing apparatuses 1 displayed in the operational status table 71, and the number of alarms decreases when an abnormal processing stop is solved and processing is resumed. The number of warnings in the operational status table 71 is also updated based on the apparatus operational information continuously transmitted from each of the substrate processing apparatuses 1. The number of warnings increases when a new normal processing stop has occurred in any of the substrate processing apparatuses 1 displayed in the operational status table 71, and the number of warnings decreases when a normal processing stop is resolved and processing is resumed. When an abnormal or normal processing stop has occurred in any of the substrate processing apparatuses 1 that are not displayed in the operational status table 71 (i.e., in which any processing stop has not yet occurred), this substrate processing apparatus 1 is newly displayed in the operational status table 71, together with the number of alarms and the number of warnings.

In the processing apparatus group management system 6, a sorting processing part 711 is provided in the field of each display item in the operational status table 71. The sorting processing part 711 may, for example, be a button with two upward and downward arrows displayed thereon. In the processing apparatus group management system 6, when a sorting processing part 711 that corresponds to one display item is operated (i.e., clicked) by an operator, the display controller 62 (see FIG. 4) performs a sorting process for this display item in the operational status table 71 (e.g., processing for changing the sequence of this display item in ascending or descending order), and causes the display 87 to display the result of the process, i.e., the operational status table 71. By operating the sorting processing part 711, the operator is also able to display the arrangement of the substrate processing apparatuses 1 in the operational status table 71 that is restored to the initial sequence (e.g., the sequence in which processing stops have occurred). Note that the sorting processing part 711 does not necessarily have to be provided in the field of each display item, and may be provided in the fields of one or more display items among a plurality of display items.

In the processing apparatus group management system 6, a filtering processing part 712 is provided for example above the field of each display item in the operational status table 71. The filtering processing part 712 may, for example, be a pull-down menu that displays a data list of the corresponding display item. For example, the filtering processing part 712 that is provided above the field indicating the model of each substrate processing apparatus 1 displays the models of substrate processing apparatuses 1 that are currently displayed in the operational status table 71, in list form. When one of the models is selected by an operator, the display controller 62 performs a filtering process of selecting only one or a plurality of substrate processing apparatuses 1 that correspond to the selected model from among all of the substrate processing apparatuses 1 displayed in the operational status table 71, and causes the display 87 to display the result of the process, i.e., the operational status table 71. Note that the operator may cause the filtering processing part 712 to select a plurality of models from among the models displayed in list form and perform a filtering process for the selected models. As another alternative, the operator may manually input a model to be selected to the filtering processing part 712 via the keyboard 85.

The filtering process may be performed for a plurality of display items. For example, the filtering process may be performed for the models of the substrate processing apparatuses 1 and for the installation areas thereof, and only substrate processing apparatuses 1 that correspond to one selected model and that are installed in one selected installation area may be selectively displayed on the display 87. By operating the filtering processing part 712, the operator is also able to display the operational status table 71 that is restored from before performing the filtering process. Note that the filtering processing part 712 does not necessarily have to be provided in the field of each display item, and may be provided in the fields of one or more display items among the display items.

In the example illustrated in FIG. 6, a storage processing part 713 and a readout processing part 714 are provided above the filtering processing parts 712. For example, the storage processing part 713 may be a button with the character “Store” displayed thereon, and the readout processing part 714 may be a button with the character “Read” displayed thereon. When the storage processing part 713 is operated (e.g., clicked) by an operator, processing conditions for the filtering process that are input by the operator are stored in the information storage 61. When the readout processing part 714 is operated (e.g., clicked) by an operator, one or a plurality of processing conditions for the filtering process that are stored in the information storage 61 are displayed. Then, when one of the processing conditions is selected by the operator, the display controller 62 reads and uses the selected one processing condition in the filtering process. That is, the display controller 62 uses the selected one processing condition to perform the filtering process on the operational status table 71, and causes the display 87 to display the result of the process.

In the processing apparatus group management system 6, processing conditions for the sorting process may also be stored in the information storage 61 in approximately the same manner as in the case of the filtering process, i.e., by the operator operating the storage processing part 713. Also, when the readout processing part 714 is operated by an operator, the display controller 62 may read and use a selected processing condition in the sorting process.

The processing apparatus group management system 6 is also capable of displaying the operational status table 71 that has undergone both of the filtering process and the sorting process described above on the display 87. However, the processing apparatus group management system 6 does not necessarily have to be configured to be capable of performing both of the filtering process and the sorting process on the operational status table 71, and may be configured to be capable of performing only either of the filtering process and the sorting process.

In the processing apparatus group management system 6, when an operator has selected one substrate processing apparatus 1 by clicking or any other action from among the substrate processing apparatuses 1 displayed in the operational status table 71, the display controller 62 switches the display on the display 87 so that a summary of processing stops that have occurred in the selected substrate processing apparatus 1 is displayed as illustrated in FIG. 7. In the example illustrated in FIG. 7, a summary of information about each processing stop that has occurred in the selected substrate processing apparatus 1 (i.e., abnormal stop information and normal stop information) is displayed as a processing-stop summary table 72. FIG. 7 illustrates the processing-stop summary table 72 when the substrate processing apparatus 1 that is displayed on the top in FIG. 6 is selected.

In the processing-stop summary table 72, a plurality of display items are arranged in the row direction for each of a plurality of processing stops arranged in the column direction. For example, the display items may include the date and time of occurrence of each processing stop, the apparatus identifier of each substrate processing apparatus 1, the model of each substrate processing apparatus 1, the indication as to whether each processing stop is abnormal or normal, the name of the component in which each processing stop has occurred (e.g., MPC5 that indicates the fifth processing unit 21), a stop identifier indicating the type of each processing stop, and a stop content that indicates a summary of each processing stop. In the field of the indication as to whether the processing stop is abnormal or normal, “Alarm” may be displayed in the case of an abnormal condition, and “Warning” may be displayed in the case of a normal condition. The display items are, however, not limited to the example described above, and may be modified in various ways.

A case is also possible in which two or more substrate processing apparatuses 1 are selected in the operational status table 71 (see FIG. 6), and a summary of information about each processing stop that has occurred in each of the two or more substrate processing apparatuses 1 is displayed in the processing-stop summary table 72. The processing apparatus group management system 6 may also be configured such that, when an operator has selected one processing stop by clicking or any other action from among the processing stops displayed in the processing-stop summary table 72, detailed information about the selected processing stop (e.g., processing necessary to return from the processing stop) is displayed on the display 87.

In the example illustrated in FIG. 6, a notification part 76 is provided above the filtering processing parts 712. The notification part 76 may, for example, be a button with a bell-shaped mark 761 displayed thereon. Note that the shape of the mark 761 may be modified in various ways. In the processing apparatus group management system 6, the apparatus operational information also includes information about the occurrence of events relating to the prediction about the occurrence of abnormal conditions in the substrate processing apparatuses 1. The prediction about the occurrence of abnormal conditions refers to predicting the occurrence of the aforementioned abnormal processing stops before the occurrence thereof. The events relating to the prediction about the occurrence of abnormal conditions refer to signs of abnormal processing stops that occur before the occurrence of the abnormal processing stops. Details of the events will be described later.

When an event relating to the prediction about the occurrence of abnormal conditions has occurred, event occurrence information is included in the apparatus operational information that is continuously transmitted from the substrate processing apparatuses 1 to the processing apparatus group management system 6 and stored in the information storage 61. Then, the display controller 62 confirms that the event occurrence information is included in the apparatus operational information, and causes the display 87 to offer a notification display 762 that notifies the operator of the occurrence of the event, on the notification part 76. In the example illustrated in FIG. 6, the notification display 762 corresponds to an approximately circular pattern displayed at the upper right of the mark 761 of the notification part 76. Note that the shape of the notification display 762 may be modified in various ways. Also, the notification display 762 does not necessarily have to be a pattern of a predetermined shape, and for example, flashing of the mark 761 of the notification part 76 may be used as the notification display. As another alternative, the notification display in any other form that is visually recognizable by an operator may be provided on the display 87.

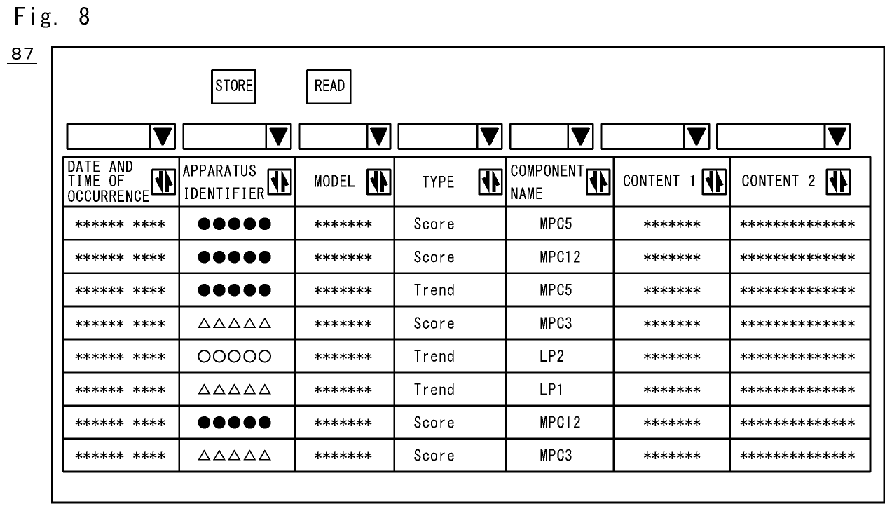

When the operator has operated the notification display 762 by, for example, clicking the notification part 76, the display controller 62 switches the display on the display 87 so that an event table 77 that displays event information about each event that has occurred in list form is displayed on the display 87 as illustrated in FIG. 8. In the example illustrated in FIG. 8, a summary of events that have occurred in the substrate processing apparatuses 1 that are connected to the processing apparatus group management system 6 is displayed as the event table 77. In the event table 77, a plurality of display items are arranged in the row direction for each of a plurality of events arranged in the column direction. The display items may include, for example, the date and time of occurrence of each event, the apparatus identifier of the substrate processing apparatus 1 in which the event has occurred, the model of each substrate processing apparatus 1, the type of each event, the name of the component in which each event has occurred (e.g., MPC5 that indicates the fifth processing unit 21), and event contents 1 and 2 each indicating a summary of each event. The display items are, however, not limited to the example described above, and may be modified in various ways.

In the field of the type of the event, for example, “Score” or “Trend” is displayed. “Score” refers to the occurrence of an event (i.e., the sign of an abnormal condition) according to the prediction about the occurrence of abnormal conditions by scoring, and “Trend” refers to the occurrence of an event according to the prediction about the occurrence of abnormal conditions by trend analysis.

In the prediction about the occurrence of abnormal conditions by scoring, for example, each processing unit 21 is used as a target, and measurement data about a predetermined processing operation performed in the processing unit 21 is compared with reference data, and the amount of difference of the measurement data from the reference data is statistically processed as a score. Then, if the score is greater than a predetermined threshold value (e.g., Level 4), it is determined that an event has occurred. Examples of the target for the prediction about the occurrence of abnormal conditions by scoring include the temperature and flow rate of a processing liquid supplied from the nozzle to substrates 9 in the processing unit 21. The scoring may be done by, for example a method similar to those described in Japanese Patent Application Laid-Open No. 2019-139416 and Japanese Patent Application Laid-Open No. 2019-140196, the disclosure of which are herein incorporated by reference.

In the prediction about the occurrence of abnormal conditions by trend analysis, for example, each processing unit 21 is used as a target, and time-series data about a predetermined processing operation performed in the processing unit 21 is acquired to determine whether the time-series data falls within a range between predetermined upper and lower limit values. Then, if the time-series data satisfies a predetermined condition concerning crossings of the upper and lower limit values, it is determined that an event has occurred. Examples of the predetermined condition include a condition in which a crossing of the upper limit value has occurred a predetermined number of times, a condition in which the amount of one crossing of the upper limit value is greater than or equal to a predetermined value, a condition in which a crossing of the lower limit value has occurred a predetermined number of times, and a condition in which the amount of one crossing of the lower limit value is greater than or equal to a predetermined value. One example of the target for the prediction about the occurrence of abnormal conditions by trend analysis may be a shift distance of the nozzle that supplies a processing liquid to substrates 9 in the processing unit 21. The shift distance of the nozzle refers to the amount of shift when a cylinder that is returning to the point of origin is displaced from the position of the origin in a mechanism for moving the nozzle, such as a linear actuator.

In the field of the content 1 (i.e., event content 1) in the event table 77, for example, what kind of an event has occurred is displayed according to scoring or trend analysis. For example, when the score crosses Level 4 according to scoring, the occurrence of an event is displayed in the field of the event content 1. In the field of the content 2 (i.e., event content 2), for example, a module that is the cause of occurrence of the event (e.g., a nozzle that supplies a processing liquid to substrates 9) and a condition that is the cause of occurrence of the event in the module (e.g., an abnormal temperature of the processing liquid supplied from the nozzle) are displayed.

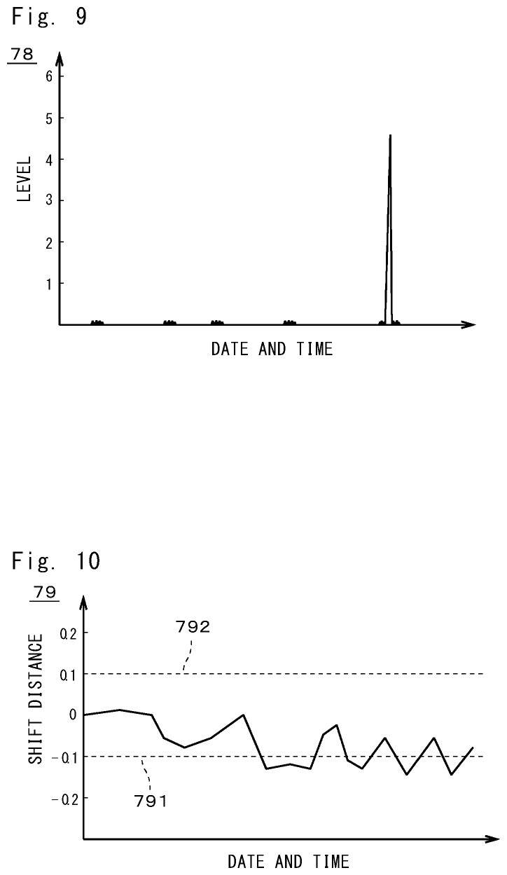

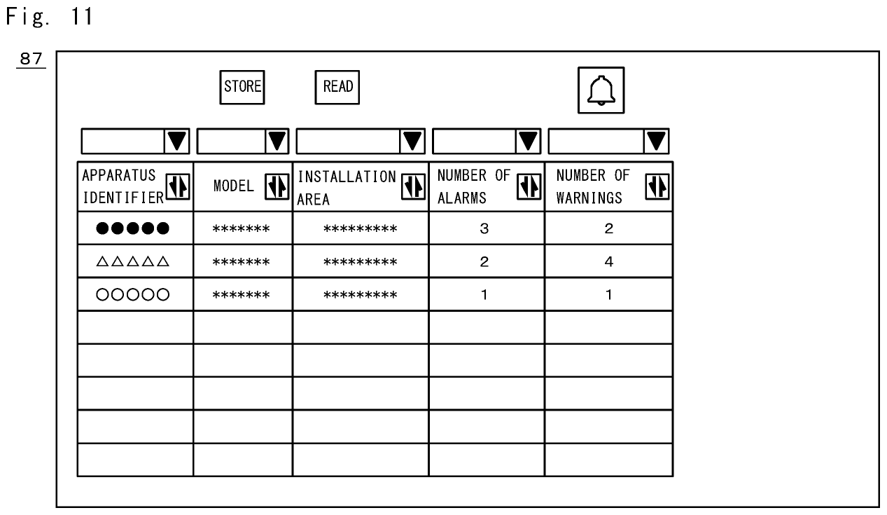

In the processing apparatus group management system 6, when an operator has selected one event by clicking or any other action from among the events displayed in the event table 77, the display controller 62 switches the display on the display 87 so that details on the selected event are displayed as illustrated in FIGS. 9 and 10. The selection of one event may be made by, for example, clicking a button (not shown) provided at, for example, the right end of the row corresponding to the one event.

FIG. 9 shows one example of detailed display when an event with the event type of “Score” is selected in the event table 77. In FIG. 9, a graph 78 shows the condition of the module that is the cause of occurrence of the event in time sequence that includes an instant of time when the event has occurred. Specifically, the graph 78 shows the time sequence of the score for the temperature of the processing liquid supplied from the nozzle serving as the module to substrates 9. In the graph, the horizontal axis represents the date and time, and the vertical axis represents the score. The graph 78 shows that an event occurs suddenly at the time when the score has exceeded Level 4 on the right side of the center in the horizontal axis, and at the other times, the score is always maintained at or near Level 0 (i.e., in the normal condition). Above the graph 78, a button 780 is provided, and when the button 780 is operated (e.g., clicked) by an operator, the display on the display 87 is switched and returns to the display of the event table 77 illustrated in FIG. 8.

FIG. 10 shows one example of detailed display when an event with the event type of “Trend” is selected in the event table 77. In FIG. 10, a graph 79 shows the condition of the module that is the cause of occurrence of the event in time sequence that includes an instant of time when the event has occurred. Specifically, the graph 79 shows the time sequence of the shift distance of the nozzle, which serves as the module. In the graph, the horizontal axis represents the date and time, and the vertical axis represents the shift distance of the nozzle. A shift distance of zero indicates the ideal condition in which the nozzle has no shifts. In the graph 79, a lower limit value 791 and an upper limit value 792 for the shift distance are indicated by broken lines. The graph 79 shows that a phenomenon in which the shift distance crosses the lower limit value 791 has occurred relatively high frequently over a relatively long period of time, and a notification that indicates the occurrence of an event has been given when the crossing of the lower limit value 791 has occurred a predetermined number of times or over a predetermined period of time. Above the graph 79, a button 790 is provided, and when the button 790 is operated (e.g., clicked) by an operator, the display on the display 87 is switched and returns to the display of the event table 77 illustrated in FIG. 8.

Above the event table 77, a button 770 is provided, and when the button 770 is operated (e.g., clicked) by an operator, the display on the display 87 is switched and returns to the display of the operational status table 71 illustrated in FIG. 11. As illustrated in FIG. 11, after the event table 77 is confirmed by the operator, the notification display 762 (see FIG. 6) is not displayed in the notification part 76. This indicates that there are no unconfirmed events. When a new event has occurred, the notification display 762 is displayed again in the notification part 76.

As illustrated in FIG. 8, a sorting processing part 771 is provided in the field of each display item in the event table 77. The sorting processing part 771 may, for example, be a button with two upward and downward arrows displayed thereon. In the processing apparatus group management system 6, when the sorting processing part 771 that corresponds to one display item is operated (e.g., clicked) by an operator, the display controller 62 (see FIG. 4) performs a sorting process for this display item in the event table 77 (e.g., processing for changing the sequence of this display item in ascending or descending order), and causes the display 87 to display the result of the process, i.e., the event table 77. By operating the sorting processing part 771, the operator is also able to display the arrangement of a plurality of events in the event table 77 that is restored to the initial sequence (e.g., the sequence in which the events have occurred). Note that the sorting processing part 771 does not necessarily have to be provided in the field of each display item, and may be provided in the fields of one or more display items among the display items.

In the processing apparatus group management system 6, a filtering processing part 772 is provided, for example, above the field of each display item in the event table 77. The filtering processing part 772 may, for example, be a pull-down menu that displays a data list of the corresponding display item. For example, the filtering processing part 772 that is provided above the field indicating the model of each substrate processing apparatus 1 displays the models of the substrate processing apparatuses 1 that are currently displayed in the event table 77, in list form in response to an operator's operation. Then, when one model is selected by the operator, the display controller 62 performs a filtering process for selecting only one or a plurality of substrate processing apparatuses 1 that correspond to the selected model from among all of the substrate processing apparatuses 1 displayed in the event table 77, and causes the display 87 to display the result of the process, i.e., the event table 77. Note that the operator may cause the filtering processing part 772 to select a plurality of models from among the models displayed in list form and perform the filtering process for the selected models. As another alternative, the operator may manually input a model to be selected to the filtering processing part 772 via the keyboard 85.

The filtering process may be performed for a plurality of display items. For example, the fliting process may be performed for the models of the substrate processing apparatuses 1 and for the types of events, and only substrate processing apparatuses 1 that correspond to one selected model and in which an event of the selected type has occurred may be selectively displayed on the display 87. By operating the filtering processing part 772, the operator is also able to display the event table 77 that is restored from before performing the filtering process. Note that the filtering processing part 772 does not necessarily have to be provided in the field of each display item, and may be provided in the fields of one or more display items among the display items.

In the example illustrated in FIG. 8, a storage processing part 773 and a readout processing part 774 are provided above the filtering processing parts 772. For example, the storage processing part 773 may be a button with the character “Store” displayed thereon, and the readout processing part 774 may be a button with the character “Read” displayed thereon. When the storage processing part 773 is operated (e.g., clicked) by an operator, processing conditions for the filtering process that are input by the operator are stored in the information storage 61. When the readout processing part 774 is operated (e.g., clicked) by an operator, one or a plurality of processing conditions for the filtering process that are stored in the information storage 61 are displayed. Then, when one of the processing conditions is selected by the operator, the display controller 62 reads and uses the selected one processing condition in the filtering process. That is, the display controller 62 uses the selected one processing condition to perform the filtering process on the event table 77, and causes the display 87 to display the result of the process.

In the processing apparatus group management system 6, processing conditions for the sorting process that is performed on the event table 77 may also be stored in the information storage 61 in approximately the same manner as in the case of the filtering process, i.e., by the operator operating the storage processing part 773. Also, when the readout processing part 774 is operated by an operator, the display controller 62 may read and use a selected processing condition in the sorting process that is performed on the event table 77.

The processing apparatus group management system 6 is also capable of displaying the event table 77 that has undergone both of the filtering process and the sorting process described above on the display 87. However, the processing apparatus group management system 6 does not necessarily have to be capable of performing both of the filtering process and the sorting process on the event table 77, and may be capable of performing only either of the filtering process and the sorting process.

As described thus far, the processing apparatus group management system 6 is a system for managing the operational statuses of a processing apparatus group that is a group of a plurality of substrate processing apparatuses 1. The processing apparatus group management system 6 includes the information storage 61, the information display (i.e., display 87), and the display controller 62. The information storage 61 stores the apparatus-specific information and the apparatus operational information, the apparatus-specific information being information specific to each of the substrate processing apparatuses 1, and the apparatus operational information being information about the operational statuses of the substrate processing apparatuses 1 and being continuously transmitted from the substrate processing apparatuses 1. The display controller 62 causes the display 87 to display the operational status of each of the substrate processing apparatuses 1 as the operational status table 71 in accordance with the apparatus-specific information and the apparatus operational information about the substrate processing apparatuses 1. The operational status table 71 includes a plurality of display items that include the apparatus identifier used to identify each of the substrate processing apparatuses 1 and the number of times an abnormal processing stop occurs in each substrate processing apparatus 1 (i.e., the number of alarms). Accordingly, it is possible to collectively manage the operational statuses of the substrate processing apparatuses 1.

As described above, it is preferable that the display controller 62 performs at least one process out of the filtering process and the sorting process for one or more display items among the aforementioned display items in the operational status table 71, and causes the display 87 to display the result of the process. Accordingly, it is possible to easily extract the desired substrate processing apparatus 1 whose operational status is desired to be checked in detail, from among the substrate processing apparatuses 1.

As described above, it is preferable that the information storage 61 stores a processing condition for the aforementioned at least one process, and the display controller 62 reads and uses the processing condition stored in the information storage 61 in the aforementioned at least one process. This hastens the filtering process and/or the sorting process that is/are performed under the desired processing condition.

As described above, it is preferable that the aforementioned display items further include the installation area in which each of the substrate processing apparatuses 1 is installed. This facilitates the identification of the occurrence of an abnormal processing stop that may relate to the installation areas of the substrate processing apparatuses 1.

As described above, it is preferable that the aforementioned display items further include the number of times a normal processing stop occurs in each substrate processing apparatus 1 (i.e., the number of warnings). By in this way displaying both of the number of times an abnormal processing stop occurs (i.e., the number of alarms) and the number of times a normal processing stop occurs due to regular automatic maintenance or any other reason, it is possible to prevent a normal processing stop from being misdetected as an abnormal processing stop.

As described above, the apparatus operational information preferably includes information about the occurrence of an event relating to the prediction about the occurrence of abnormal conditions in the substrate processing apparatuses 1, and the display controller 62 preferably causes the display 87 to offer the notification display 762 that provides notification of the occurrence of the event in accordance with the apparatus operational information. It is also preferable that, when the notification display 762 is operated, the display controller 62 causes the display 87 to display the event table 77 that displays event information about each event that has occurred in list form. This enables an operator to easily recognize the occurrence of an event relating to the prediction about the occurrence of abnormal conditions. The operator is also able to easily check each event in detail. By the operator taking preventive measures to prevent the occurrence of an abnormal processing stop, it is possible to reduce the occurrence of an abnormal processing stop in each substrate processing apparatus 1.

As described above, it is preferable that the display controller 62 performs at least one process out of the filtering process and the sorting process for one or more display items among a plurality of display items in the event table 77, and causes the display 87 to display the result of the process. This makes it possible to easily extract the desired event that is desired to be checked in detail from among a plurality of events.

As described above, it is preferable that, when one event is selected in the event table 77, the display controller 62 causes the display 87 to display the status of the module that is the cause of occurrence of the one event in the substrate processing apparatus 1 in which the one event has occurred, in time sequence that includes an instant of time when the one event has occurred. This makes it possible to speedily check the status of the module that is the cause of occurrence of the event.

In the processing apparatus group management system 6, when it is allowed to take some time to check the status of the aforementioned module, one processing unit 21 in which an event desired to be checked has occurred may be identified in accordance with the situation of the occurrence of events in each of the processing units 21, and the event that is desired to be checked may be extracted from among a plurality of events occurring in the identified processing unit 21 and displayed in time sequence, as described in Japanese Patent Application Laid-Open No. 2019-140196.

The processing apparatus group management method described above includes the step of storing the apparatus-specific information and the apparatus operation information, the apparatus-specific information being information specific to each of a plurality of substrate processing apparatuses 1, and the apparatus operational information being information about the operational statuses of the substrate processing apparatuses 1 and being continuously transmitted from the substrate processing apparatuses 1 (step S11), and the step of causing the information display (i.e., display 87) to display the operational status of each of the substrate processing apparatuses 1 as the operational status table 71 in accordance with the apparatus-specific information and the apparatus operational information about the substrate processing apparatuses 1 (step S12). The operational status table 71 includes a plurality of display items that include the apparatus identifier used to identify each of the substrate processing apparatuses 1, and the number of times an abnormal processing stop occurs in each substrate processing apparatus 1. Accordingly, it is possible to collectively manage the operational statuses of the substrate processing apparatuses 1 as described above.

As described above, the computer 8 executes the program 89 to perform the step of storing the apparatus-specific information and the apparatus operational information, the apparatus-specific information being information specific to each of a plurality of substrate processing apparatuses 1, and the apparatus operational information being information about the operational statuses of the substrate processing apparatuses 1 and being continuously transmitted from the substrate processing apparatuses 1 (step S11), and the step of causing the information display (i.e., display 87) to display the operational status of each of the substrate processing apparatuses 1 as the operational status table 71 in accordance with the apparatus-specific information and the apparatus operational information about the substrate processing apparatuses 1 (step S12). The operational status table 71 includes a plurality of display items that include the apparatus identifier used to identify each of the substrate processing apparatuses 1, and the number of times an abnormal processing stop occurs in each substrate processing apparatus 1. Accordingly, it is possible to collectively manage the operational statuses of the substrate processing apparatuses 1 as described above.

The processing apparatus group management system 6, the processing apparatus group management method, and the program 89 described above may be modified in various ways.

The event table 77 does not necessarily have to allow an operator to store and read processing conditions for the filtering process and the sorting process, and may omit the storage processing part 773 and the readout processing part 774. The event table 77 does not necessarily have to allow execution of the filtering process and the sorting process.

The processing apparatus group management system 6 does not necessarily have to be capable of displaying the event-related information as illustrated in FIGS. 9 and 10 in time sequence. Besides, it is not an absolute necessity for the display 87 to offer the notification display 762 that provides notification of the occurrence of an event and to display the event table 77.

In the example described above, when an event has occurred in any of the substrate processing apparatuses 1, the notification display 762 is displayed without identification of the substrate processing apparatus 1 in which the event has occurred, but the present invention is not limited to this example. For example, the notification display 762 may be displayed together with information such as the apparatus identifier of the substrate processing apparatus 1 in which the event has occurred, in order to make it possible to identify the substrate processing apparatus 1 in which the event has occurred.

The operational status table 71 does not necessarily have to allow an operator to store and read processing conditions for the filtering process and the sorting process, and may omit the storage processing part 713 and the readout processing part 714. The operational status table 71 also does not necessarily have to allow an operator to perform the filtering process and the sorting process.

As described above, the display items in the operational status table 71 may be modified in various ways. For example, the display items do not necessarily have to include the number of warnings. The display items also do not necessarily have to include the installation area of each substrate processing apparatus 1.

The substrate processing apparatus 1 described above may also be used to process glass substrates other than semiconductor substrates, such as glass substrates used in flat panel displays including liquid crystal displays and organic electroluminescence displays (EL), and glass substrates used in any other display. The substrate processing apparatus 1 described above may also be used to process substrates such as optical disk substrates, magnetic disk substrates, photo-magnetic disk substrates, photomask substrates, ceramic substrates, and solar cell substrates.

The configurations of the preferred embodiments and variations described above may be appropriately combined as long as there are no mutual inconsistencies.

While the invention has been shown and described in detail, the foregoing description is in all aspects illustrative and not restrictive. It is therefore to be understood that numerous modifications and variations can be devised without departing from the scope of the invention.

### REFERENCE SIGNS LIST

1 Substrate processing apparatus
6 Processing apparatus group management system
8 Computer
9 Substrate
61 Information storage
62 Display controller
71 Operational status table
77 Event table
87 Display
89 Program
762 Notification display
S11 and S12 Step

1. A processing apparatus group management system for managing operational statuses of a processing apparatus group that is a group of a plurality of substrate processing apparatuses,
the processing apparatus group management system comprising:
an information storage that stores apparatus-specific information and apparatus operational information, the apparatus-specific information being information specific to each of a plurality of substrate processing apparatuses, and the apparatus operational information being information about operational statuses of said plurality of substrate processing apparatuses and being continuously transmitted from said plurality of substrate processing apparatuses;
an information display; and
a display controller that causes said information display to display the operational status of each of said plurality of substrate processing apparatuses as an operational status table in accordance with said apparatus-specific information and said apparatus operational information about said plurality of substrate processing apparatuses,
wherein said operational status table includes a plurality of display items that include:
an apparatus identifier used to identify each of said plurality of substrate processing apparatuses; and
a number of times an abnormal processing stop occurs in each of said plurality of substrate processing apparatuses.

2. The processing apparatus group management system according to claim 1, wherein
said display controller performs at least one process out of a filtering process and a sorting process for one or more display items of said plurality of display items in said operational status table, and causes said information display to display a processing result.

3. The processing apparatus group management system according to claim 2, wherein
said information storage stores a processing condition for said at least one process, and
said display controller reads and uses said processing condition stored in said information storage in said at least one process.

4. The processing apparatus group management system according to claim 1, wherein
said plurality of display items further include an installation area in which each of said plurality of substrate processing apparatuses is installed.

5. The processing apparatus group management system according to claim 1, wherein
said plurality of display items further include a number of times a normal processing stop occurs in each of said plurality of substrate processing apparatuses.

6. The processing apparatus group management system according to claim 1, wherein
said apparatus operational information includes information about occurrence of an event relating to prediction about occurrence of an abnormal condition in said plurality of substrate processing apparatuses,
said display controller causes said information display to offer a notification display that provides notification of occurrence of said event in accordance with said apparatus operational information, and
when said notification display is operated, said display controller causes said information display to display an event table in which event information about each event that has occurred is displayed in list form.

7. The processing apparatus group management system according to claim 6, wherein
said display controller performs at least one process out of a filtering process and a sorting process for one or more display items of a plurality of display items in said event table, and causes said information display to display a processing result.

8. The processing apparatus group management system according to claim 6, wherein
when one event is selected in said event table, said display controller causes said information display to display a condition of a module that is a cause of occurrence of said one event in a substrate processing apparatus in which said one event has occurred, in time sequence that includes an instant of time when said one event has occurred.

9. A processing apparatus group management method for managing operational statuses of a processing apparatus group that is a group of a plurality of substrate processing apparatuses,
the processing apparatus group management method comprising;
a) storing apparatus-specific information and apparatus operational information, the apparatus-specific information being information specific to each of a plurality of substrate processing apparatuses, and the apparatus operational information being information about operational statuses of said plurality of substrate processing apparatuses and being continuously transmitted from said plurality of substrate processing apparatuses; and
b) causing an information display to display the operational status of each of said plurality of substrate processing apparatuses as an operational status table in accordance with said apparatus-specific information and said apparatus operational information about said plurality of substrate processing apparatuses,
wherein said operational status table includes a plurality of display items that include:
an apparatus identifier used to identify each of said plurality of substrate processing apparatuses; and
a number of times an abnormal processing stop occurs in each of said plurality of substrate processing apparatuses.

10. A program for managing operational statuses of a processing apparatus group that is a group of a plurality of substrate processing apparatuses,
said program being executed by a computer to:
a) store apparatus-specific information and apparatus operational information, the apparatus-specific information being information specific to each of a plurality of substrate processing apparatuses, and the apparatus operational information being information about operational statuses of said plurality of substrate processing apparatuses and being continuously transmitted from said plurality of substrate processing apparatuses; and
b) cause an information display to display the operational status of each of said plurality of substrate processing apparatuses as an operational status table in accordance with said apparatus-specific information and said apparatus operational information about said plurality of substrate processing apparatuses,
wherein said operational status table includes a plurality of display items that include:
an apparatus identifier used to identify each of said plurality of substrate processing apparatuses; and
a number of times an abnormal processing stop occurs in each of said plurality of substrate processing apparatuses.
